(19) United States
(12) Patent Application Publication
(10) Pub. No.: US 2024/0306429 A1
(43) Pub. Date: Sep. 12, 2024

(54) DISPLAY DEVICE AND METHOD OF MANUFACTURING THE SAME

(71) Applicant: Samsung Display Co., LTD., Yongin-si (KR)

(72) Inventors: JUNGI KIM, Yongin-si (KR); HYE SUN KIM, Yongin-si (KR); SANGHYUN YUN, Yongin-si (KR); GWANGMIN CHA, Yongin-si (KR)

(21) Appl. No.: 18/403,505

(22) Filed: Jan. 3, 2024

(30) Foreign Application Priority Data
Mar. 9, 2023 (KR) 10-2023-0031452

(51) Int. Cl. H10K 59/122; H10K 59/12

(52) U.S. Cl. CPC H10K 59/122; H10K 59/1201

(57) ABSTRACT

A display device includes a substrate having light-emitting areas, a pixel electrode above the substrate, a pixel-defining layer exposing a portion of the pixel electrode, and including a first portion having a first thickness and having an upper surface having liquid repellency, and a second portion having a second thickness that is less than the first thickness and having an upper surface that is lyophilic, and a light-emitting layer above the pixel electrode.

### CROSS-REFERENCED TO RELATED APPLICATION

This application claims priority to, and the benefit of, Korean Patent Application No. 10-2023-0031452, filed on Mar. 9, 2023, in the Korean Intellectual Property Office, the content of which in its entirety is herein incorporated by reference.

### BACKGROUND

### 1. Field

The disclosure relates to a display device for displaying an image, and a method of manufacturing the display device.

### 2. Description of the Related Art

As information technology develops, the importance of a display device as a connection medium between a user and information is being highlighted. For example, the use of display devices, such as the like a liquid crystal display device (LCD), an organic light-emitting display device (OLED), a plasma display device (PDP), a quantum dot display device, etc., is increasing.

In one or more embodiments, the display device includes sub-pixels implementing red, green, and blue visible light. A light-emitting layer may be formed in each of the sub-pixels. The light-emitting layer may be formed using an inkjet printing method.

### SUMMARY

Embodiments provide a display device with improved display quality.

Embodiments provide a method of manufacturing the display device with improved manufacturing process efficiency.

A display device according to one or more embodiments may include a substrate having light-emitting areas, a pixel electrode above the substrate, a pixel-defining layer exposing a portion of the pixel electrode, and including a first portion having a first thickness and having an upper surface having liquid repellency, and a second portion having a second thickness that is less than the first thickness and having an upper surface that is lyophilic, and a light-emitting layer above the pixel electrode.

The pixel-defining layer may have a single-layer structure in which the first portion and the second portion are integrated.

The light-emitting layer may cover the second portion, and is spaced apart from the upper surface of the first portion.

The first portion may be between a respective pair of the light-emitting areas that are adjacent to each other and that emit light of different respective colors, wherein the second portion is between another respective pair of the light-emitting areas that are adjacent to each other and that emit light of a same color.

The pixel-defining layer may include a positive photoresist.

The first thickness may be about 1.6 μm or less, wherein the second thickness is about 0.8 μm or less.

A taper angle of the first portion may be greater than a taper angle of the second portion.

The light-emitting layer may include a composition for the light-emitting layer, wherein a contact angle of the composition for the light-emitting layer with respect to the upper surface of the first portion is about 50 degrees to about 70 degrees, and wherein a contact angle of the composition for the light-emitting layer with respect to the upper surface of the second portion is about 10 degrees to about 20 degrees.

The pixel-defining layer may include a liquid repellent containing a fluorine-based material, wherein a density of the liquid repellent in an area adjacent to the upper surface of the first portion is greater than a density of the liquid repellent in an area adjacent to the upper surface of the second portion.

The upper surface of the second portion may have a concave and convex structure.

A method of manufacturing a display device according to one or more embodiments may include forming a pixel electrode above a substrate having light-emitting areas, forming a preliminary pixel-defining layer covering the pixel electrode on the substrate, forming a pixel-defining layer exposing a portion of the pixel electrode, and including a first portion having a first thickness and having an upper surface having liquid repellency, and a second portion having a second thickness that is less than the first thickness and having an upper surface that is lyophilic, by patterning the preliminary pixel-defining layer using a mask, and forming a light-emitting layer on the pixel electrode.

The method may further include forming the first portion and the second portion to be integrally formed together through a same process.

The preliminary pixel-defining layer may include a positive photoresist.

The preliminary pixel-defining layer may include a liquid repellent containing a fluorine-based material.

The mask may include a halftone mask.

The mask may include a slit mask.

The upper surface of the second portion may have a concave and convex structure after the forming of the pixel-defining layer.

The light-emitting layer may be formed through an inkjet printing process.

The light-emitting layer may be formed to cover the second portion, and to be spaced apart from the upper surface of the first portion.

The first portion may be between a respective pair of the light-emitting areas that are adjacent to each other and that emit light of different respective colors, wherein the second portion is formed between another respective pair of the light-emitting areas that are adjacent to each other and that emit light of same color.

In the display device according to embodiments, the display device may include the pixel-defining layer, and the pixel-defining layer may include the first portion having the first thickness and having the upper surface that has liquid repellency, and the second portion having the second thickness that is less than the first thickness and having the upper surface which be lyophilic. For example, the pixel-defining layer may have a single-layer structure in which the first portion and the second portion are integrated.

That is, according to the manufacturing method of the display device according to the embodiments, the pixel-defining layer including the first portion and the second portion may be formed through a single exposure process.

Accordingly, liquid repellency and lyophilic of the upper surface of the pixel-defining layer, which are suitable in the process of forming the light-emitting layer, may be concurrently or substantially simultaneously realized through a single-layer structure of the pixel-defining layer. Accordingly, efficiency of the process of forming the pixel-defining layer may be increased, and costs may be reduced. In addition, efficiency of the inkjet printing process for forming the light-emitting layer may be increased, and a display quality of the display device may be improved.

It is to be understood that both the foregoing general description and the following detailed description are exemplary and explanatory and are intended to provide further explanation of the embodiments as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to one or more embodiments.

FIG. 2 is an enlarged view illustrating an enlarged area A of FIG. 1.

FIG. 3 is a cross-sectional view taken along the line I-I′ of FIG. 2.

FIGS. 4 to 9 are cross-sectional views illustrating a manufacturing method of the display device of FIG. 1.

FIG. 10 is a cross-sectional view illustrating a display device according to one or more other embodiments.

FIGS. 11 and 12 are cross-sectional views illustrating a manufacturing method of the display device of FIG. 10.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. In one or more embodiments, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include

A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

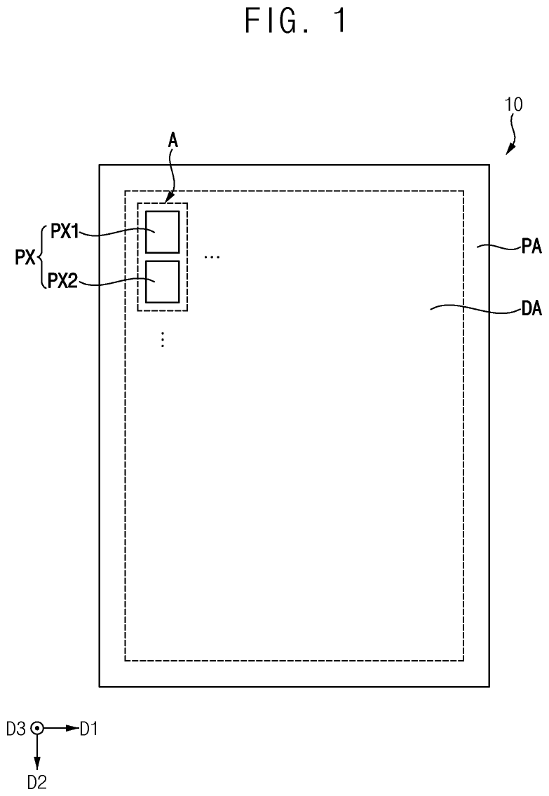

FIG. 1 is a plan view illustrating a display device according to one or more embodiments.

Referring to FIG. 1, the display device 10 according to one or more embodiments may be divided into a display area DA and a peripheral area PA. The display area DA may display an image, and the peripheral area PA may be located around the display area DA. For example, the peripheral area PA may surround the display area DA.

In one or more embodiments, the display device 10 may have a quadrangular shape in a plan view. However, the present disclosure is not necessarily limited thereto, and the display device 10 may have various shapes in a plan view. In this case, a plane may be defined from a first direction D1, and a second direction D2 intersecting the first direction D1. A third direction D3 may be perpendicular to the plane.

A pixel PX may be located in the display area DA. The pixel PX may include a first pixel PX1, and a second pixel PX2 adjacent to the first pixel PX1. For example, the second pixel PX2 may be adjacent to the first pixel PX1 in the second direction D2.

The pixel PX may emit light. For example, the first pixel PX1 and the second pixel PX2 may concurrently or substantially simultaneously emit light. In one or more embodiments, if the first pixel PX1 emits light, the second pixel PX2 may not emit light, and if the second pixel PX2 emits light, the first pixel PX1 may not emit light. The display area DA may display an image.

A driver may be located in the peripheral area PA. The driver may provide a signal and/or voltage to the pixel PX. For example, the driver may include a gate driver and a data driver.

The display device 10 may include an organic light-emitting display device, an inorganic light-emitting display device, a quantum dot light-emitting display device, a micro LED display device, a nano LED display device, a plasma display device, or a liquid crystal display device. Hereinafter, for convenience of description, a case in which the display device 10 is an organic light-emitting display device will be described as an example.

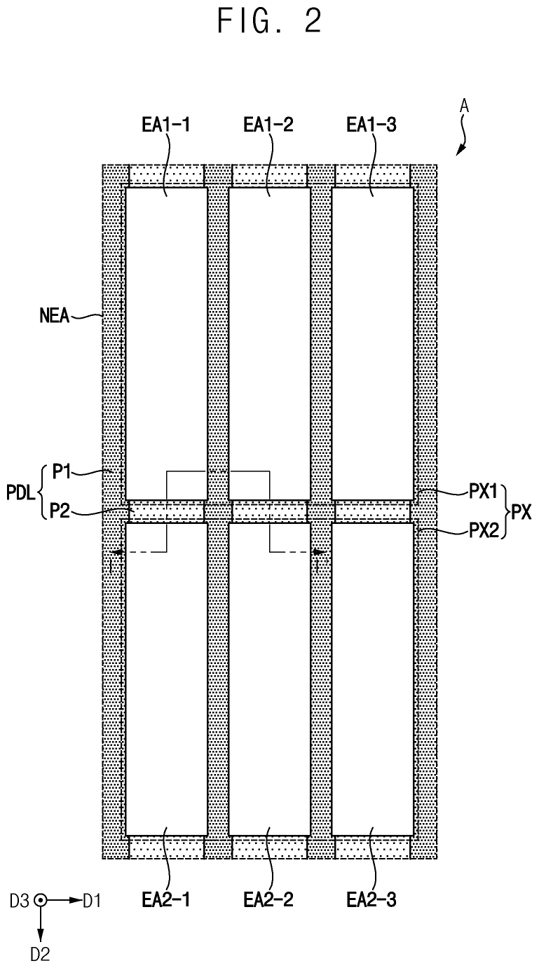

FIG. 2 is an enlarged view illustrating an enlarged area A of FIG. 1.

Referring to FIGS. 1 and 2, as described above, the pixel PX may include the first pixel PX1 and the second pixel PX2.

The first pixel PX1 may include a 1-1st light-emitting area EA1-1, a 1-2nd light-emitting area EA1-2, and a 1-3rd light-emitting area EA1-3. In one or more embodiments, the 1-1st light-emitting area EA1-1, the 1-2nd light-emitting area EA1-2, and the 1-3rd light-emitting area EA1-3 may be arranged in the first direction D1. The 1-1st light-emitting area EA1-1, the 1-2nd light-emitting area EA1-2, and the 1-3rd light-emitting area EA1-3 may emit light.

The second pixel PX2 may include a 2-1st light-emitting area EA2-1, a 2-2nd light-emitting area EA2-2, and a 2-3rd light-emitting area EA2-3. The 2-1st light-emitting area EA2-1, the 2-2nd light-emitting area EA2-2, and the 2-3rd light-emitting area EA2-3 may be arranged in the first direction D1. In this case, the 2-1st light-emitting area EA2-1 may be adjacent to the 1-1st light-emitting area EA1-1 in the second direction D2, the 2-2nd light-emitting area EA2-2 may be adjacent to the 1-2nd light-emitting area EA1-2 in the second direction D2, and the 2-3rd light-emitting area EA2-3 may be adjacent to the 1-3rd light-emitting area EA1-3 in the second direction D2.

The 1-1st light-emitting area EA1-1, the 1-2nd light-emitting area EA1-2, and the 1-3rd light-emitting area EA1-3 may emit light of different respective colors, and the 1-1st light-emitting area EA2-1, the 2-2nd light-emitting area EA2-2, and the 2-3rd light-emitting area EA2-3 may emit light of different respective colors. In one or more embodiments, the 1-1st light-emitting area EA1-1 and the 2-1st light-emitting area EA2-1 may emit light of a same color, the 1-2nd light-emitting area EA1-2 and the 2-2nd light-emitting area EA2-2 may emit light of a same color, and the 1-3rd light-emitting area EA1-3 and the 2-3rd light-emitting area EA2-3 may emit light of a same color.

For example, the 1-1st light-emitting area EA1-1 and the 2-1st light-emitting area EA2-1 may emit red light, the 1-2nd light-emitting area EA1-2 and the 2-2nd light-emitting area EA1-2 may emit green light, and the 1-3rd light-emitting area EA1-3 and the 2-3rd light-emitting area EA2-3 may emit blue light. However, the present disclosure is not necessarily limited thereto.

In one or more embodiments, although the light-emitting areas are illustrated as having a same size as each other in FIG. 2, the present disclosure is not necessarily limited thereto. In one or more embodiments, a size of each of the 1-3rd light-emitting area EA1-3 and the 2-3rd light-emitting area EA2-3 may be larger than a size of each of the 1-1st light-emitting area EA1-1, the 1-2nd light-emitting area EA1-2, the 2-1st light-emitting area EA2-1, and the 2-2nd light-emitting area EA2-2.

In addition, although the light-emitting areas are illustrated as having a quadrangular planar shape in FIG. 2, the present disclosure is not necessarily limited thereto. In one or more embodiments, the light-emitting areas may have a polygonal planar shape other than a quadrangle or a track-type planar shape.

The 1-1st light-emitting area EA1-1, the 1-2nd light-emitting area EA1-2, the 1-3rd light-emitting area EA1-3, the 2-1st light-emitting area EA2-1, the 2-2nd light-emitting area EA2-2, and the 2-3rd light-emitting area EA2-3 may be surrounded by a non-light-emitting area NEA in a plan view. For example, the non-light-emitting area NEA may have a grid shape in a plan view. The non-light-emitting area NEA may not emit light.

A pixel-defining layer PDL may be located in the non-light-emitting area NEA. That is, the pixel-defining layer PDL may surround the light-emitting areas in a plan view. For example, the pixel-defining layer PDL may entirely overlap the non-light-emitting area NEA, and may have a grid shape in a plan view.

In one or more embodiments, the pixel-defining layer PDL may include a first portion P1 and a second portion P2. That is, the pixel-defining layer PDL may have a single-layer structure in which the first portion P1 and the second portion P2 are integrated.

The first portion P1 may be positioned between light-emitting areas that are adjacent to each other and that emit light of different respective colors among the light-emitting areas. For example, the first portion P1 may be positioned between the 1-1st light-emitting area EA1-1 and the 1-2nd light-emitting area EA1-2, between the 1-2nd light-emitting area EA1-2 and the 1-3rd light-emitting area EA1-3, between the 2-1st light-emitting area EA2-1 and the 2-2nd light-emitting area EA2-2, and between the 2-2nd light-emitting area EA2-2 and the 2-3^{rd} light-emitting area EA2-3.

The second portion P2 may be positioned between light-emitting areas that are adjacent to each other and that emit light of a same color among the light-emitting areas. For example, the second portion P2 may be positioned between the 1-1st light-emitting area EA1-1 and the 2-1st light-emitting area EA2-1, between the 1-2nd light-emitting area EA1-2 and the 2-2nd light-emitting area EA2-2, and between the 1-3rd light-emitting area EA1-3 and the 2-3rd light-emitting area EA2-3.

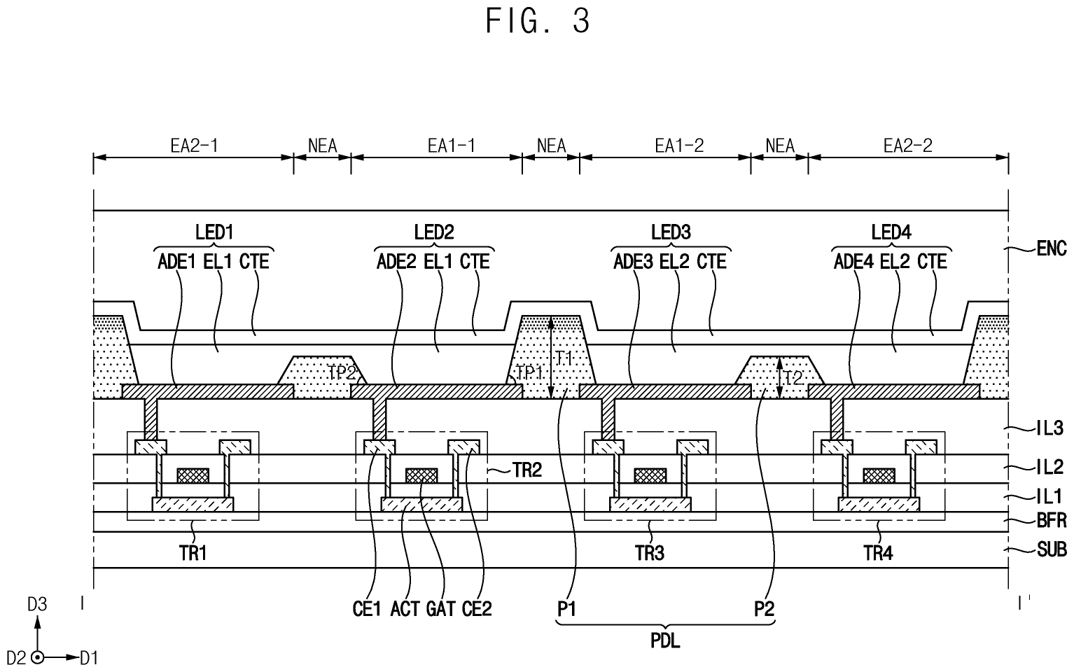

The pixel-defining layer PDL will be described later in more detail with reference to FIG. 3.

FIG. 3 is a cross-sectional view taken along the line I-I′ of FIG. 2.

In one or more embodiments, in FIG. 3, for convenience of description, only the 1-1st light-emitting area EA1-1, the 1-2nd light-emitting area EA1-2, the 2-1st light-emitting area EA2-1, and the 2-2nd light-emitting area EA2-2 are illustrated. The 1-3rd light-emitting area EA1-3 and the 2-3rd light-emitting area EA2-3 may have substantially same cross-sectional structure as the 1-1st light-emitting area EA1-1, the 1-2nd light-emitting area EA1-2, the 2-1st light-emitting area EA2-1, and the 2-2nd light-emitting area EA2-2.

Referring to FIGS. 2 and 3, the display device 10 may include a substrate SUB, a buffer layer BFR, first to fourth driving elements TR1, TR2, TR3, and TR4, first to third insulating layers IL1, IL2, and IL3, a pixel-defining layer PDL, first to fourth light-emitting elements LED1, LED2, LED3, and LED4, and an encapsulation layer ENC.

The first to fourth driving elements TR1, TR2, TR3, and TR4 may have substantially the same structure as each other. For example, each of the first to fourth driving elements TR1, TR2, TR3, and TR4 may include an active pattern ACT, a gate electrode GAT, a first connection electrode CE1, and a second connection electrode CE2.

The first light-emitting element LED1 may be located in the 2-1st light-emitting area EA2-1. The first light-emitting element LED1 may include a first pixel electrode ADE1, a first light-emitting layer EL1, and a common electrode CTE. The second light-emitting element LED2 may be located in the 1-1st light-emitting area EA1-1. The second light-emitting element LED2 may include a second pixel electrode ADE2, the first light-emitting layer EL1, and the common electrode CTE. The third light-emitting element LED3 may be located in the 1-2nd light-emitting area EA1-2. The third light-emitting element LED3 may include a third pixel electrode ADE3, a second light-emitting layer EL2, and the common electrode CTE. The first light-emitting element LED4 may be located in the 2-1st light-emitting area EA2-1. The fourth light-emitting element LED4 may include a fourth pixel electrode ADE4, the second light-emitting layer EL2, and the common electrode CTE.

The substrate SUB may include a transparent or opaque material. In one or more embodiments, examples of materials that can be used as the substrate SUB may include glass, quartz, plastic, or the like. These may be used alone or in combination with each other.

The buffer layer BFR may be located on (e.g., above) the substrate SUB. The buffer layer BFR may reduce or prevent diffusion of impurities, such as oxygen, moisture, or the like to an upper portion of the substrate SUB through the substrate SUB. The buffer layer BFR may include an inorganic insulating material, such as a silicon compound or a metal oxide.

In one or more embodiments, a barrier layer may be additionally located between the substrate SUB and the buffer layer BFR. The barrier layer may include an inorganic insulating material.

The active pattern ACT may be located on the buffer layer BFR. In one or more embodiments, the active pattern ACT may include a silicon semiconductor material or an oxide semiconductor material. Examples of the silicon semiconductor material that can be used as the active pattern ACT may include amorphous silicon, polycrystalline silicon, or the like. Examples of the oxide semiconductor material that can be used as the active pattern ACT may include IGZO (InGaZnO), ITZO (InSnZnO), or the like.

In one or more embodiments, the first insulating layer IL1 may be located on the buffer layer BFR. The first insulating layer IL1 may cover the active pattern ACT. In one or more other embodiments, the first insulating layer IL1 may be located in a pattern form on the active pattern ACT to expose a portion of the active pattern ACT. For example, the first insulating layer IL1 may be located on the active pattern ACT in a pattern form to overlap the gate electrode GAT. The first insulating layer IL1 may include an inorganic insulating material. Examples of inorganic insulating materials that can be used as the first insulating layer IL1 may include silicon oxide, silicon nitride, silicon oxynitride, or the like.

The gate electrode GAT may be located on the first insulating layer IL1. In one or more embodiments, the gate electrode GAT may include a metal, an alloy, a conductive metal oxide, a transparent conductive material, or the like.

The second insulating layer IL2 may be located on the first insulating layer IL1. In one or more embodiments, the second insulating layer IL2 may cover the gate electrode GAT. The second insulating layer IL2 may include an inorganic insulating material. Examples of inorganic insulating materials that can be used as the second insulating layer IL2 may include silicon oxide, silicon nitride, silicon oxynitride, or the like.

The first connection electrode CE1 and the second connection electrode CE2 may be located on the second insulating layer IL2. The first connection electrode CE1 and the second connection electrode CE2 may be electrically connected to the active pattern ACT through contact holes formed in the second insulating layer IL2. Each of the first connection electrode CE1 and the second connection electrode CE2 may include a metal, an alloy, a conductive metal oxide, a transparent conductive material, or the like.

The third insulating layer IL3 may be located on the second insulating layer IL2. The third insulating layer IL3 may cover the first connection electrode CE1 and the second connection electrode CE2. The third insulating layer IL3 may include an organic insulating material. Examples of organic insulating materials that can be used as the third insulating layer IL3 may include photoresist, polyacryl-based resin, polyimide-based resin, polyamide-based resin, siloxane-based resin, acrylic-based resin, epoxy-based resin, or the like.

In one or more embodiments, configuration, arrangement structure, and connection structure of each of the driving elements TR1, TR2, TR3, and TR4 and the insulating layers IL1, IL2, and IL3 described with reference to FIG. 3 are only examples, and may be variously changed according to embodiments.

The first to fourth pixel electrodes ADE1, ADE2, ADE3, and ADE4 may be located on the third insulating layer IL3. The first to fourth pixel electrodes ADE1, ADE2, ADE3, and ADE4 may be electrically connected to the driving elements TR1, TR2, TR3, and TR4 through contact holes formed in, or defined by, the third insulating layer IL3, respectively. For example, the first pixel electrode ADE1 may be electrically connected to the first driving element TR1, the second pixel electrode ADE2 may be electrically connected to the second driving element TR2, the third pixel electrode ADE3 may be electrically connected to the third driving element TR3, and the fourth pixel electrode ADE4 may be electrically connected to the fourth driving element TR4. The first to fourth pixel electrodes ADE1, ADE2, ADE3, and ADE4 may include a metal, an alloy, a conductive metal oxide, a transparent conductive material, or the like.

The pixel-defining layer PDL may be located on the third insulating layer IL3. In one or more embodiments, the pixel-defining layer PDL may include an organic insulating material. Examples of organic insulating materials that can be used as the pixel-defining layer PDL may include polyacrylic resin, polyimide resin, acrylic resin, or the like. These may be used alone or in combination with each other.

In one or more embodiments, the pixel-defining layer PDL may define a pixel opening exposing a portion of each of the first to fourth pixel electrodes ADE1, ADE2, ADE3, and ADE4. The pixel-defining layer PDL may define an area corresponding to the pixel opening as the light-emitting areas, and a portion where the pixel-defining layer PDL is located may be defined as the non-light-emitting area NEA.

For example, a portion of the first pixel electrode ADE1 exposed by the pixel-defining layer PDL may correspond to the 2-1st light-emitting area EA2-1, a portion of the second pixel electrode ADE2 exposed by the pixel-defining layer PDL may correspond to the 1-1st light-emitting area EA1-1, a portion of the third pixel electrode ADE3 exposed by the pixel-defining layer PDL may correspond to the 1-2nd emitting area EA1-2, and a portion of the fourth pixel electrode ADE4 exposed by the pixel-defining layer PDL may correspond to the 2-2nd light-emitting area EA2-2.

As described above with reference to FIG. 2, the pixel-defining layer PDL may include the first portion P1 and the second portion P2.

In one or more embodiments, a thickness of the first portion P1 and a thickness of the second portion P2 may be different from each other. For example, a first thickness T1 of the first portion P1 may be greater than a second thickness T2 of the second portion P2. That is, a height from an upper surface of the third insulating layer IL3 to an upper surface of the first portion P1 may be greater than a height from the upper surface of the third insulating layer IL3 to an upper surface of the second portion P2. In this case, the upper surface of the first portion P1 may refer to a surface of the first portion P1 that is farthest from the third insulating layer IL3 among the first portion P1. Also, the upper surface of the second portion P2 may refer to a surface of the second portion P2 that is farthest from the third insulating layer IL3 among the second portion P2.

In one or more embodiments, the first thickness T1 of the first portion P1 may be about 1.6 μm or less. For example, the first thickness T1 of the first portion P1 may be about 0.8 μm to about 1.6 μm, for example about 1.0 μm to about 1.2 μm. Also, the second thickness T2 of the second portion P2 may be about 0.8 μm or less. For example, the second thickness T2 of the second portion P2 may be about 0.4 μm to about 0.8 μm, for example about 0.5 μm to about 0.6 μm.

In one or more embodiments, a first taper angle TP1 of the first portion P1 may be greater than a second taper angle TP2 of the second portion P2. In the present specification, a taper angle means a smaller angle among angles between a side surface of each of the first portion P1 and the second portion P2 and the upper surfaces of the corresponding pixel electrodes. That is, the side surface of each of the first portion P1 and the second portion P2 may extend from the upper surface of the pixel electrode in the third direction D3 at a taper angle (e.g., predetermined taper angle).

In one or more embodiments, a first taper angle TP1 may be about 40 degrees to about 70 degrees, for example about 40 degrees to about 65 degrees. In addition, a second taper angle TP2 may be about 20 degrees to about 60 degrees, for example about 20 degrees to about 50 degrees.

As described above, the first portion P1 and the second portion P2 may be integrally formed. That is, the pixel-defining layer PDL may have a single-layer structure in which the first portion P1 and the second portion P2 are integrated. For example, the pixel-defining layer PDL having a single layer structure including the first portion P1 and the second portion P2 may be formed by adjusting an exposure amount through an exposure process using a halftone mask or a slit mask. In other words, the pixel-defining layer PDL may include a photoresist. For example, the pixel-defining layer PDL may include a positive photoresist.

In one or more embodiments, the upper surface of the first portion P1 may have liquid repellency, and the upper surface of the second portion P2 may be lyophilic. In the present specification, liquid repellency may mean a property that repels a solution (e.g., predetermined solution), and that does not permeate the solution well. In addition, lyophilic means a property having excellent affinity for the solution. For example, the solution may have a relatively low surface bonding force with a liquid repellency surface, and the solution located on the liquid repellency surface may have increased surface tension. In addition, the solution may have a relatively high surface bonding force with a lyophilic surface, and the solution located on the lyophilic surface may have reduced surface tension.

When a surface on which the solution is located has liquid repellency, the solution may have a larger contact angle than if a surface on which the solution is located is lyophilic. In this case, the contact angle means an angle formed between a tangential line of a surface of the solution and the surface at a point where the solution is in contact with the surface on which the solution is located. As liquid repellency increases, the contact angle may increase.

In one or more embodiments, the pixel-defining layer PDL may be formed from a composition for forming a pixel-defining layer including a liquid repellent. That is, the pixel-defining layer PDL may include the liquid repellent. The liquid repellent may contain a fluorine-based material.

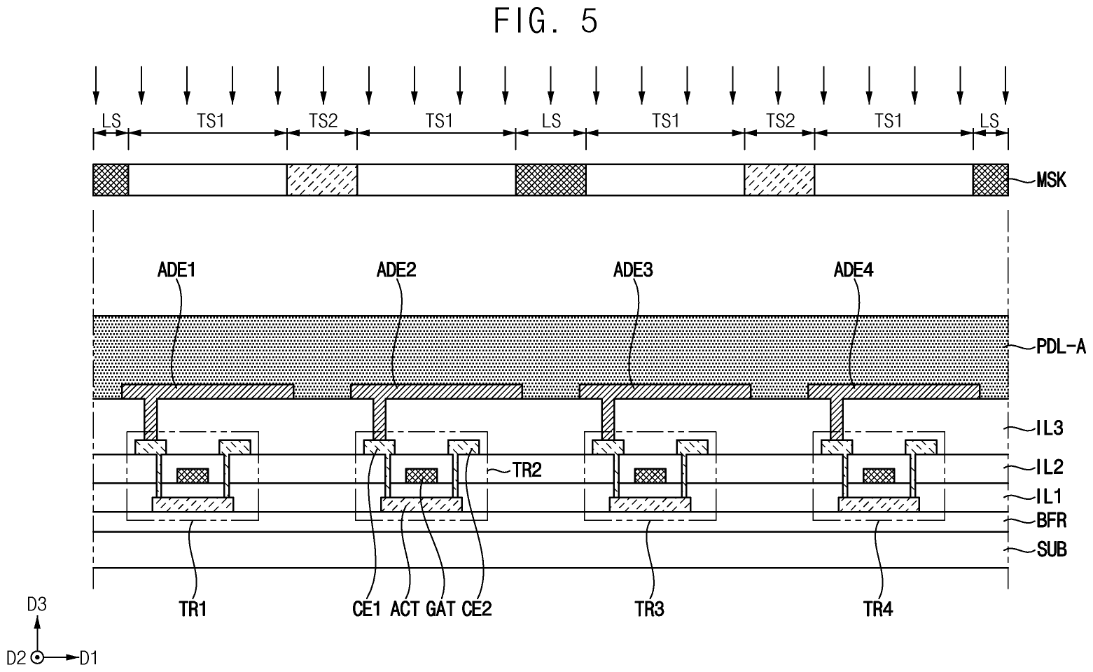

In the process of forming the pixel-defining layer PDL, the liquid repellent may be concentrated in an area adjacent to the upper surface of the first portion P1 in the pixel-defining layer PDL. That is, a density of the liquid repellent in the area adjacent to the upper surface of the first portion P1 may be greater than a density of the liquid repellent in an area adjacent to the upper surface of the second part P2. Accordingly, the upper surface of the first portion P1 may have liquid repellency, whereas the upper surface of the second portion P2 may be lyophilic. This will be described later in detail with reference to FIG. 5.

The first light-emitting layer EL1 and the second light-emitting layer EL2 may be located in the pixel opening of the pixel-defining layer PDL. In this case, the first light-emitting layer EL1 and the second light-emitting layer EL2 may overlap the second portion P2 in a plan view. For example, the first light-emitting layer EL1 and the second light-emitting layer EL2 may cover the second portion P2, and may be spaced apart from the upper surface of the first portion P1.

For example, the first light-emitting layer EL1 may be located on the first pixel electrode ADE1 and the second pixel electrode ADE2, and the second light-emitting layer EL2 may be located on the third pixel electrode ADE3 and the fourth pixel electrode ADE4. That is, the first light-emitting layer EL1 may cover the second portion P2 positioned between the 2-1st light-emitting area EA2-1 and the 1-1st light-emitting area EA1-1. The second light-emitting layer EL2 may cover the second portion P2 positioned between the 1-2nd light-emitting area EA1-2 and the 2-2nd light-emitting area EA2-2.

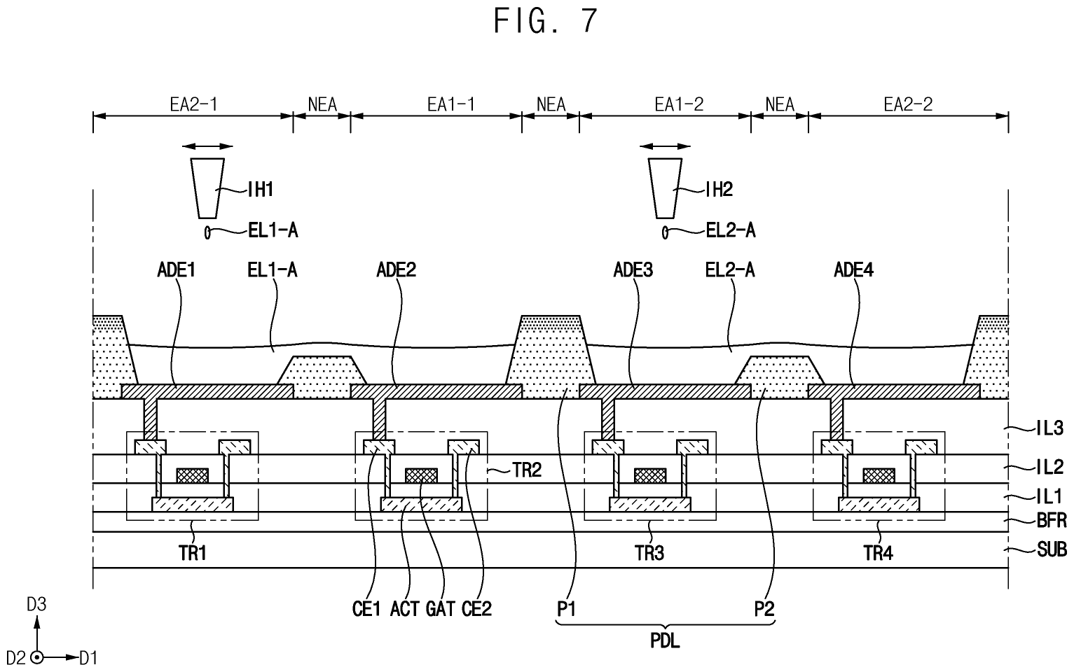

The first light-emitting layer EL1 and the second light-emitting layer EL2 may include an organic light-emitting material. In one or more embodiments, the first light-emitting layer EL1 and the second light-emitting layer EL2 may be formed through an inkjet printing process. This will be described later in more detail with reference to FIG. 7. The organic light-emitting material may include a low molecular organic compound or a high molecular organic compound. Examples of the low molecular organic compound may include copper phthalocyanine, diphenylbenzidine, tris-(8-hydroxyquinoline) aluminum, or the like. Examples of the high molecular organic compound may include poly(3,4-ethylenedioxythiophene), polyaniline, poly-phenylenevinylene, and polyfluorene. These may be used alone or in combination with each other.

The common electrode CTE may be located to cover the first light-emitting layer EL1, the second light-emitting layer EL2, and the pixel-defining layer PDL. For example, the common electrode CTE may be entirely located on an upper surface of the pixel-defining layer PDL and in the pixel opening of the pixel-defining layer PDL. A portion of the common electrode CTE located in the pixel opening may overlap the pixel electrodes ADE1, ADE2, ADE3, and ADE4. The common electrode CTE may include a conductive material, such as a metal, an alloy, a conductive metal nitride, a conductive metal oxide, or a transparent conductive material. The common electrode CTE may have a single-layer structure or a multi-layer structure including a plurality of conductive layers.

The encapsulation layer ENC may be located on the common electrode CTE. The encapsulation layer ENC may cover the first to fourth light-emitting elements LED1, LED2, LED3, and LED4. In one or more embodiments, the encapsulation layer ENC may include at least one inorganic encapsulation layer and at least one organic encapsulation layer. In one or more embodiments, the encapsulation layer ENC may include a first inorganic encapsulation layer located on the common electrode CTE, an organic encapsulation layer located on the first inorganic encapsulation layer, and a second organic encapsulation layer located on the organic encapsulation layer.

According to embodiments, the display device 10 may include the pixel-defining layer PDL, and the pixel-defining layer PDL may include the first portion P1 having the first thickness T1 and having the upper surface which has liquid repellency and the second portion P2 having the second thickness T2 that is less than the first thickness T1 and having the upper surface that is lyophilic. For example, the pixel-defining layer PDL may have a single-layer structure in which the first portion P1 and the second portion P2 are integrated.

Accordingly, in the process of forming the light-emitting layer using the inkjet printing process, the composition for forming a light-emitting layer that is discharged to the light-emitting areas may overflow to the upper surface of the second portion P2. That is, the composition for forming a light-emitting layer discharged to light-emitting areas adjacent to each other with the second portion P2 interposed therebetween may overlap each other on the second portion P2. On the other hand, the composition for forming a light-emitting layer may not overflow to the upper surface of the first portion P1. That is, the composition for forming a light-emitting layer that is discharged to light-emitting areas adjacent to each other with the first portion P1 interposed therebetween may not be mixed with each other by the first portion P1.

In one or more embodiments, the first portion P1 may be positioned between light-emitting areas adjacent to each other and emitting light of different colors among the light-emitting areas, and the second portion P2 may be positioned between light-emitting areas adjacent to each other and emitting light of a same color among the light-emitting areas. Accordingly, mixing between the composition for forming a light-emitting layer discharged to light-emitting areas adjacent to each other, and which emit light of different respective colors, may be reduced or prevented. At the same time, efficiency of the inkjet printing process for forming the light-emitting layer may be increased through overlap of the composition for forming a light-emitting layer discharged to light-emitting areas adjacent to each other that emit light of a same color.

That is, according to the embodiments, liquid repellency and lyophilic properties of the upper surface of the pixel-defining layer PDL, which are suitable in the process of forming the light-emitting layer, may be concurrently or substantially simultaneously realized through a single-layer structure of the pixel-defining layer PDL. Accordingly, efficiency of the process of forming the pixel-defining layer PDL may be increased and costs may be reduced. In addition, efficiency of the inkjet printing process for forming the light-emitting layer may be increased, and a display quality of the display device 10 may be improved.

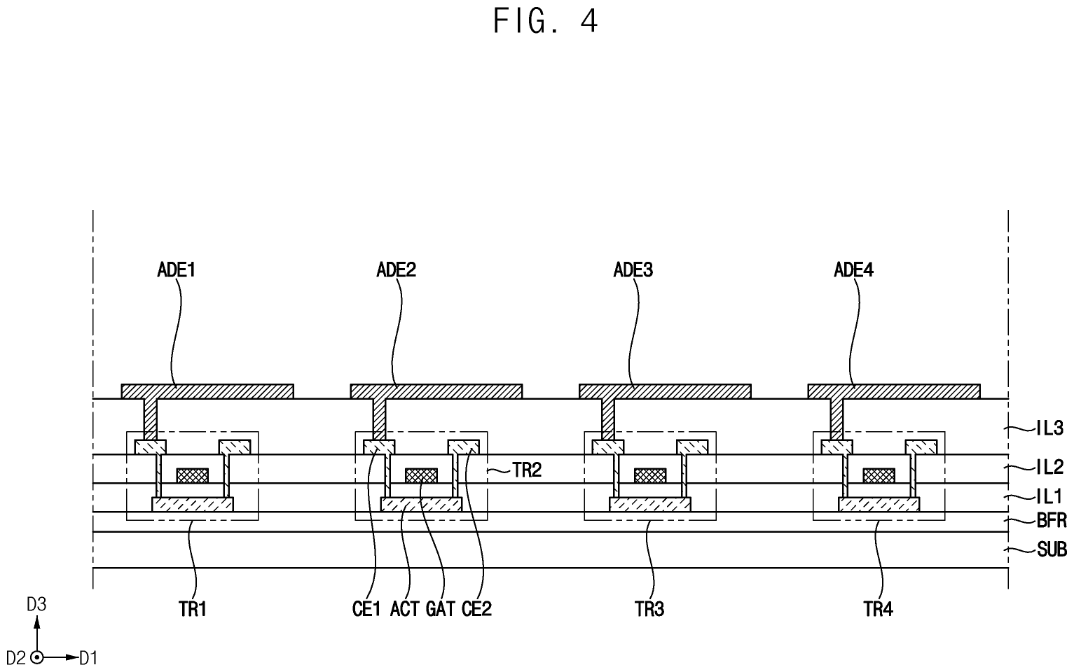

FIGS. 4 to 9 are cross-sectional views illustrating a manufacturing method of the display device of FIG. 1.

Hereinafter, a manufacturing method of the display device 10 will be described with reference to FIGS. 4 to 9.

Referring to FIG. 4, the first to fourth driving elements TR1, TR2, TR3, and TR4 and the first to fourth pixel electrodes ADE1, ADE2, ADE3, and ADE4 may be formed on the substrate SUB.

First, the buffer layer BFR may be formed on the substrate SUB. After that, the active pattern ACT may be formed on the buffer layer BFR. The active pattern ACT may be formed using an oxide semiconductor, a silicon semiconductor, an organic semiconductor, or the like.

After that, the first insulating layer IL1 may be formed on the buffer layer BFR. The first insulating layer IL1 may cover the active pattern ACT on the buffer layer BFR. The first insulating layer IL1 may be formed using an inorganic insulating material.

After that, the gate electrode GAT may be formed on the first insulating layer IL1. The gate electrode GAT may be formed using a metal, an alloy, a conductive metal oxide, a transparent conductive material, or the like.

After that, the second insulating layer IL2 may be formed on the first insulating layer IL1. The second insulating layer IL2 may cover the gate electrode GAT on the first insulating layer IL1. The second insulating layer IL2 may be formed using an inorganic insulating material.

After that, contact holes may be formed in the first insulating layer IL1 and the second insulating layer IL2. In addition, the first connection electrode CE1 and the second connection electrode CE2 may be formed on the second insulating layer IL2 to overlap the contact holes, respectively. Each of the first connection electrode CE1 and the second connection electrode CE2 may be formed using a metal, an alloy, a conductive metal oxide, a transparent conductive material, or the like. The first connection electrode CE1 and the second connection electrode CE2 may be connected to the active pattern ACT through the contact holes, respectively.

Thereafter, the third insulating layer IL3 may be formed on the second insulating layer IL2. The third insulating layer IL3 may cover the first connection electrode CE1 and the second connection electrode CE2 on the second insulation layer IL2. The third insulating layer IL3 may be formed using an organic insulating material.

Then, contact holes may be formed in the third insulating layer IL3 to overlap the first connection electrode CE1. In addition, the first to fourth pixel electrodes ADE1, ADE2, ADE3, and ADE4 may be formed on the third insulating layer IL3 to overlap the contact holes, respectively. The first to fourth pixel electrodes ADE1, ADE2, ADE3, and ADE4 may be formed of a metal, an alloy, a conductive metal oxide, a transparent conductive material, or the like.

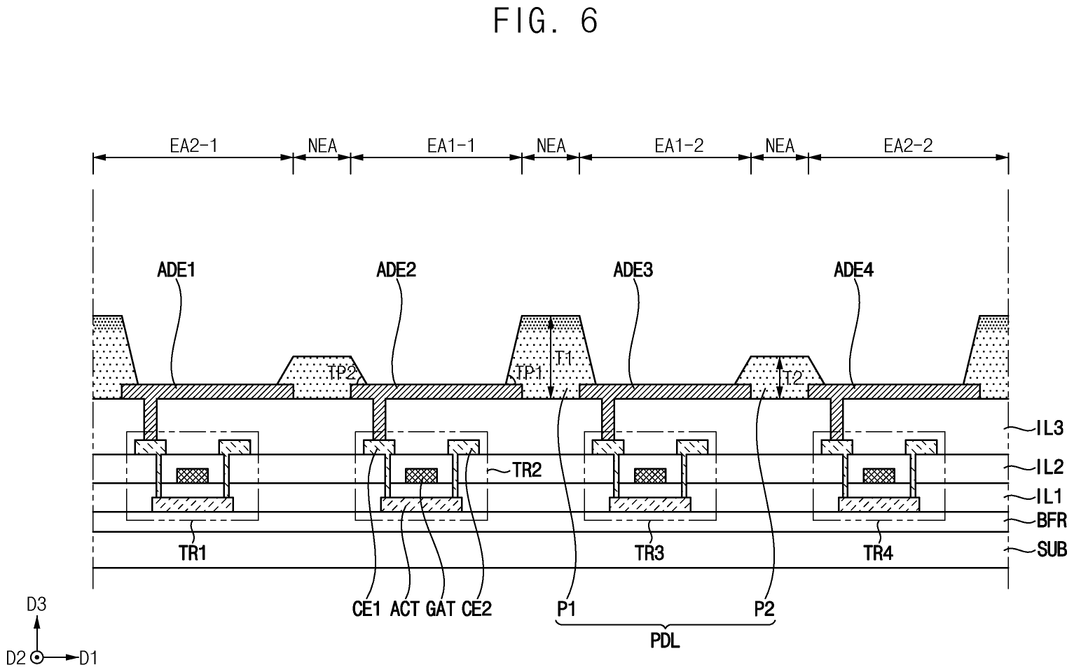

Referring to FIGS. 5 and 6, the pixel-defining layer PDL may be formed on the third insulating layer IL3.

First, a preliminary pixel-defining layer PDL-A covering the pixel electrodes ADE1, ADE2, ADE3, and ADE4 may be formed on the third insulating layer IL3. The preliminary pixel-defining layer PDL-A may be formed by applying a composition for forming a pixel-defining layer on the third insulating layer IL3. In one or more embodiments, the composition for forming a pixel-defining layer may include an organic insulating material. Examples of organic insulating materials that may be used as the composition for forming a pixel-defining layer may include polyacrylic resins, polyimide-based resins, acrylic resins, or the like. These may be used alone or in combination with each other. In addition, the composition for forming a pixel-defining layer may include the liquid repellent containing a fluorine-based material. Accordingly, the preliminary pixel-defining layer PDL-A may include the liquid repellent.

Thereafter, the pixel-defining layer PDL may be formed by patterning the preliminary pixel-defining layer PDL-A. As shown in FIG. 6, the pixel-defining layer PDL may be formed to expose a portion of each of the pixel electrodes ADE1, ADE2, ADE3, and ADE4.

In one or more embodiments, the pixel-defining layer PDL may be formed through an exposure and development process using a mask MSK. For example, the pixel-defining layer PDL may be formed by arranging the mask MSK on the preliminary pixel-defining layer PDL-A, and by exposing and developing the preliminary pixel-defining layer PDL-A.

In one or more embodiments, the mask MSK may include a light-blocking portion LS, a first light-transmitting portion TS1, and a second light-transmitting portion TS2. The light-blocking portion LS may be an area for blocking incident light incident on the mask MSK. The first light-transmitting portion TS1 and the second light-transmitting portion TS2 may be areas through which the incident light is transmitted.

In one or more embodiments, the first light-transmitting portion TS1 may have a first light transmittance, and the second light-transmitting portion TS2 may have a second light transmittance that is lower than the first light transmittance. For example, the first light-transmitting portion TS1 may transmit the incident light as it is, and the second light-transmitting portion TS2 may transmit only some of the incident light. For example, the mask MSK may be a halftone mask.

Accordingly, the incident light may not be irradiated to an area of the preliminary pixel-defining layer PDL-A corresponding to the light-blocking portion LS. In addition, most of the incident light may be irradiated to an area of the preliminary pixel-defining layer PDL-A corresponding to the first light-transmitting portion TS1. In addition, only some of the incident light may be irradiated to an area of the preliminary pixel-defining layer PDL-A corresponding to the second light-transmitting portion TS2.

In one or more embodiments, if the preliminary pixel-defining layer PDL-A is developed, all of the preliminary pixel-defining layer PDL-A corresponding to the light-blocking portion LS may remain, all of the preliminary pixel-defining layer PDL-A corresponding to the first light-transmitting portion TS1 may be removed, and only some of the preliminary pixel-defining layer PDL-A corresponding to the second light-transmitting unit TS2 may be removed. That is, the preliminary pixel-defining layer PDL-A may include a positive photoresist.

Accordingly, as shown in FIG. 6, the pixel-defining layer PDL including the first portion P1 and the second portion P2 having different thicknesses may be formed. That is, the pixel-defining layer PDL may have a single-layer structure in which the first portion P1 and the second portion P2 are integrally formed through a single exposure process.

In other words, the first portion P1 may correspond to the light-blocking portion LS, and the second portion P2 may correspond to the second light-transmitting portion TS2. The first portion P1 may have the first thickness T1, and the second portion P2 may have the second thickness T2, which is less than the first thickness T1.

In one or more embodiments, in a process of patterning the preliminary pixel-defining layer PDL-A, the liquid repellent included in the preliminary pixel-defining layer PDL-A may be concentrated in an area adjacent to an upper surface of the preliminary pixel-defining layer PDL-A. However, some of the preliminary pixel-defining layer PDL-A corresponding to the second light-transmitting portion TS2 may be removed through exposure and development processes. That is, in the area of the preliminary pixel-defining layer PDL-A corresponding to the second light-transmitting portion TS2, a portion where the liquid repellent agent is concentrated may be lost due to exposure and development processes. Accordingly, the upper surface of the second portion P2 may be lyophilic. On the other hand, the area of the preliminary pixel-defining layer PDL-A corresponding to the light-blocking portion LS may remain even after exposure and development processes. That is, in the area of the preliminary pixel-defining layer PDL-A corresponding to the light-blocking portion LS, a portion where the liquid repellent is concentrated may not be lost by the exposure and development processes. Accordingly, the upper surface of the first portion P1 may have liquid repellency.

That is, after the pixel-defining layer PDL is formed by patterning the preliminary pixel-defining layer PDL-A, a density of the liquid repellent in the area adjacent to the upper surface of the first portion P1 may be greater than that a density of the liquid repellent in the area adjacent to the upper surface of the second portion P2.

Accordingly, the pixel-defining layer PDL may include the first portion P1 having the first thickness T1 and having the upper surface that has liquid repellency, and the second portion T2 having the second thickness T2 that is less than the first thickness T1 and having the upper surface that is lyophilic.

Also, the second portion P2 corresponding to the second light-transmitting portion TS2 may have a taper angle that is less than a taper angle of the first portion P1 by exposure and development processes. That is, as described above, the first taper angle TP1 of the first portion P1 may be greater than the second taper angle TP2 of the second portion P2.

In one or more embodiments, in FIGS. 5 and 6, a case where the preliminary pixel-defining layer PDL-A includes the positive photoresist has been described, but the present disclosure is not necessarily limited thereto. In one or more embodiments, the preliminary pixel-defining layer PDL-A may include a negative photoresist. In this case, positions of the light-blocking portion LS and the first light-transmitting portion TS1 in the mask MSK may be opposite.

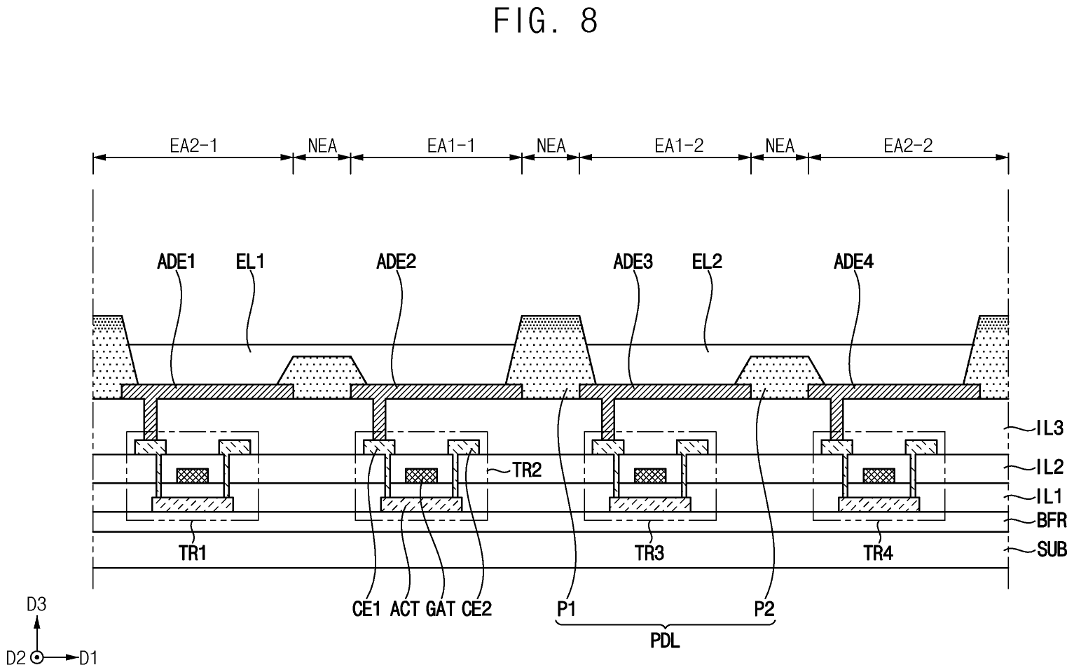

Referring to FIGS. 7 and 8, the light-emitting layers EL1 and EL2 may be formed on the pixel electrodes ADE1, ADE2, ADE3, and ADE4. The light-emitting layers EL1 and EL2 may be formed in the pixel opening of the pixel-defining layer PDL.

In one or more embodiments, the light-emitting layers EL1 and EL2 may be formed through an inkjet printing process. An example of a process of forming the light-emitting layers EL1 and EL2 through an inkjet printing process will be briefly described as follows. First, as shown in FIG. 7, a composition for forming a light-emitting layer may be provided into the pixel opening of the pixel-defining layer PDL through an inkjet printing process. For example, a composition EL1-A for forming the first light-emitting layer EL1 may be provided on the first pixel electrode ADE1 and the second pixel electrode ADE2 through a first inkjet head IH1. In addition, a composition EL2-A for forming the second light-emitting layer EL2 may be provided on the third pixel electrode ADE3 and the fourth pixel electrode ADE4 through a second inkjet head IH2.

In one or more embodiments, each of the composition EL1-A for forming the first light-emitting layer EL1 and the composition EL2-A for forming the second light-emitting layer EL2 may include an organic solvent and a functional material. As described above, in one or more embodiments, the functional material may be an organic light-emitting material.

As long as the organic solvent dissolves the organic light-emitting material, the type is not limited. Examples of the organic solvent may include toluene, xylene, ethylbenzene, diethylbenzene, mesitylene, propylbenzene, and cyclohexylbenzene, dimethoxybenzene, anisole, ethoxytoluene, phenoxytoluene, isopropylbiphenyl, dimethylanisole, phenyl acetate, phenyl propionic acid, methyl benzoate, ethyl benzoate, 2-ethylnaphthalene, 2-ethylbiphenyl, or the like. These may be used alone or in combination with each other.

As described above, the upper surface of the second portion P2 may be lyophilic with respect to the composition EL1-A for forming the first light-emitting layer EL1 and the composition EL2-A for forming the second light-emitting layer EL2. Also, the upper surface of first portion P1 may have liquid repellency with respect to the composition EL1-A for forming the first light-emitting layer EL1 and the composition EL2-A for forming the second light-emitting layer EL2. That is, a contact angle of each of the composition EL1-A for forming the first light-emitting layer EL1 and the composition EL2-A for forming the second light-emitting layer EL2 with respect to the upper surface of the first portion P1 may be greater than a contact angle of each of the composition EL1-A for forming the first light-emitting layer EL1 and the composition EL2-A for forming the second light-emitting layer EL2.

For example, the contact angle of each of the composition EL1-A for forming the first light-emitting layer EL1 and the composition EL2-A for forming the second light-emitting layer EL2 may be about 50 degrees to about 70 degrees, for example about 50 degrees to about 60 degrees. In addition, the contact angle of each of the composition EL1-A for forming the first light-emitting layer EL1 and the composition EL2-A for forming the second light-emitting layer EL2 may be about 10 degrees to about 20 degrees, for example about 15 degrees to about 20 degrees.

In other words, liquid repellency may be imparted to the upper surface of the first portion P1, and lyophilic properties may be imparted to the upper surface of the second portion P2 through exposure and development processes using the mask MSK. Accordingly, the composition for forming the light-emitting layer may overflow to the upper surface of the second portion P2. On the other hand, a phenomenon in which the composition for forming the light-emitting layer overflows to the upper surface of the first portion P1 may be reduced or prevented.

That is, according to the embodiments, liquid repellency and lyophilic properties of the upper surface of the pixel-defining layer PDL, which are suitable in the process of forming the light-emitting layer, may be concurrently or substantially simultaneously realized through a single-layer structure of the pixel-defining layer PDL. Accordingly, efficiency of the process of forming the pixel-defining layer PDL may be increased and costs may be reduced. In addition, efficiency of the inkjet printing process for forming the light-emitting layer may be increased.

After that, as shown in FIG. 8, the composition EL1-A for forming the first light-emitting layer EL1 and the composition EL2-A for forming the second light-emitting layer EL2 may be dried and/or heat treated to form the first light-emitting layer EL1 and the second light-emitting layer EL2. For example, the first light-emitting layer EL1 and the second light-emitting layer EL2 may be formed by removing at least some of the organic solvent through drying and/or heat treatment.

In one or more embodiments, the first light-emitting layer EL1 and the second light-emitting layer EL2 may cover the second portion P2, and may be formed to be spaced apart from the upper surface of the first portion P1.

For example, the first light-emitting layer EL1 may be formed on the first pixel electrode ADE1 and the second pixel electrode ADE2, and the second light-emitting layer EL2 may be formed on the third pixel electrode ADE3 and the fourth pixel electrode ADE4. That is, the first light-emitting layer EL1 may cover the second portion P2 positioned between the 2-1st light-emitting area EA2-1 and the 1-1st light-emitting area EA1-1. The light-emitting layer EL2 may cover the second portion P2 positioned between the 1-2nd light-emitting area EA1-2 and the 2-2nd light-emitting area EA2-2.

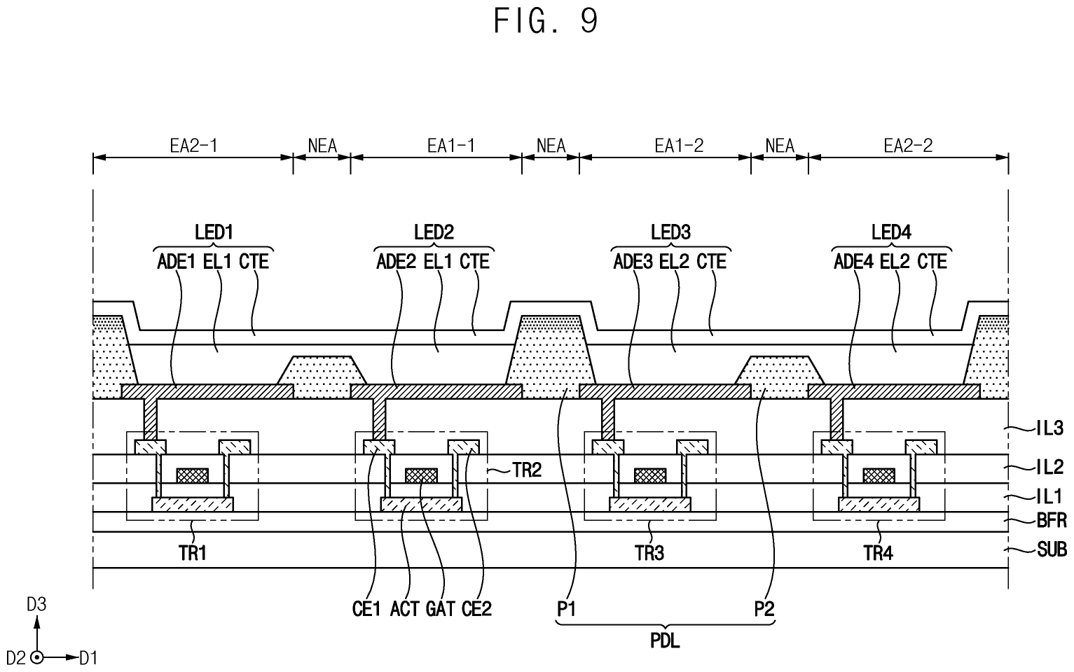

Referring to FIG. 9, the common electrode CTE may be formed on the first light-emitting layer EL1, the second light-emitting layer EL2, and the pixel-defining layer PDL. Accordingly, the light-emitting elements LED1, LED2, LED3, and LED4 may be formed on the substrate SUB. In one or more embodiments, the common electrode CTE may be formed of a metal, an alloy, a conductive metal nitride, a conductive metal oxide, a transparent conductive material, or the like.

After that, as shown in FIG. 3, the encapsulation layer ENC may be formed on the common electrode CTE. In one or more embodiments, the encapsulation layer ENC may include a first inorganic encapsulation layer located on the common electrode CTE, an organic encapsulation layer located on the first inorganic encapsulation layer, and a second organic encapsulation layer located on the organic encapsulation layer.

According to the manufacturing method of the display device 10 according to the embodiments, the pixel-defining layer PDL, which has a single-layer structure in which the first portion P1 and the second portion P2 are integrated, may be formed through a single exposure process. That is, liquid repellency and lyophilic properties of the upper surface of the pixel-defining layer PDL, which are suitable in the process of forming the light-emitting layer, may be concurrently or substantially simultaneously realized through a single exposure process. Accordingly, efficiency of the process of forming the pixel-defining layer PDL may be increased, and costs may be reduced.

In one or more embodiments, the first portion P1 may be formed between light-emitting areas adjacent to each other that emit light of different respective colors among the light-emitting areas, and the second portion P2 may be formed between light-emitting areas adjacent to each other and that emit light of a same color among the light-emitting areas. Accordingly, mixing between the composition for forming a light-emitting layer discharged to light-emitting areas adjacent to each other and that emit light of different respective colors may be reduced or prevented. At the same time, efficiency of the inkjet printing process for forming the light-emitting layer may be increased through overlap of the composition for forming a light-emitting layer discharged to light-emitting areas adjacent to each other and emitting light of a same color.

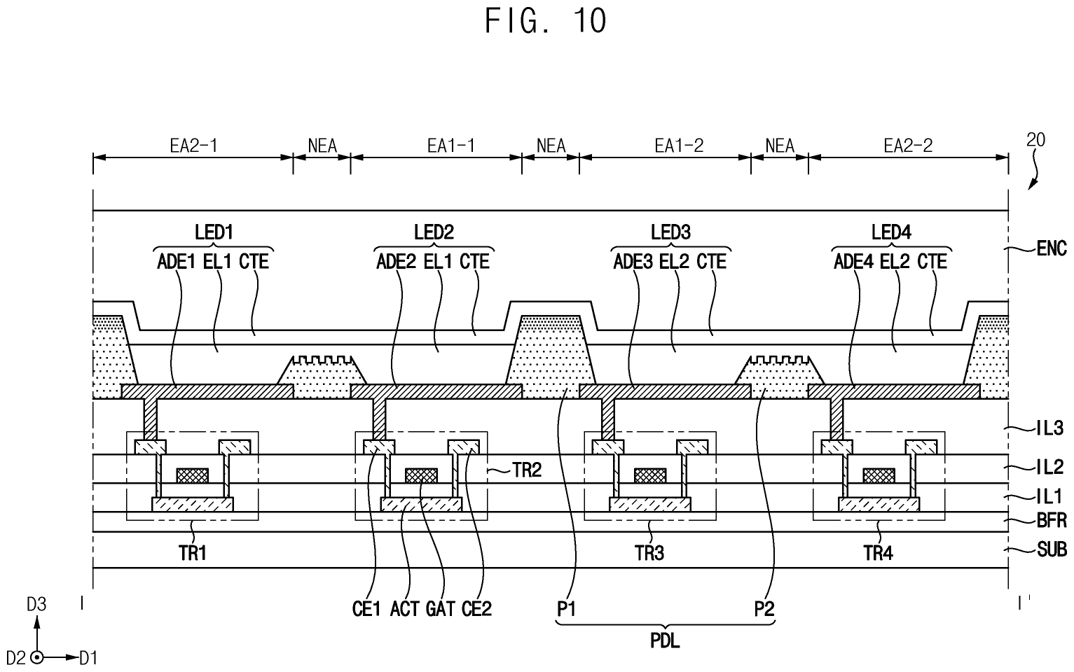

FIG. 10 is a cross-sectional view illustrating a display device according to one or more other embodiments. For example, FIG. 10 may correspond to the cross-sectional view of FIG. 3.

Referring to FIG. 10, a display device 20 may be substantially same as the display device 10 described with reference to FIGS. 1 to 3 except for a structure of the upper surface of the second portion P2. Therefore, redundant descriptions will be omitted.

In one or more embodiments, the upper surface of the second portion P2 may have a concavo-convex structure. The concavo-convex structure may have an arbitrary irregular pattern shape or an irregular concavo-convex shape on the upper surface of the second portion P2. As the upper surface of the second portion P2 has the concavo-convex structure, a contact area of the upper surface of the second portion P2 may increase. Accordingly, the likelihood of a film drop-off phenomenon may be reduced or prevented. Accordingly, light-emitting layers, such as the first light-emitting layer EL1 and the second light-emitting layer EL2, may more firmly adhere to the upper surface of the second portion P2.

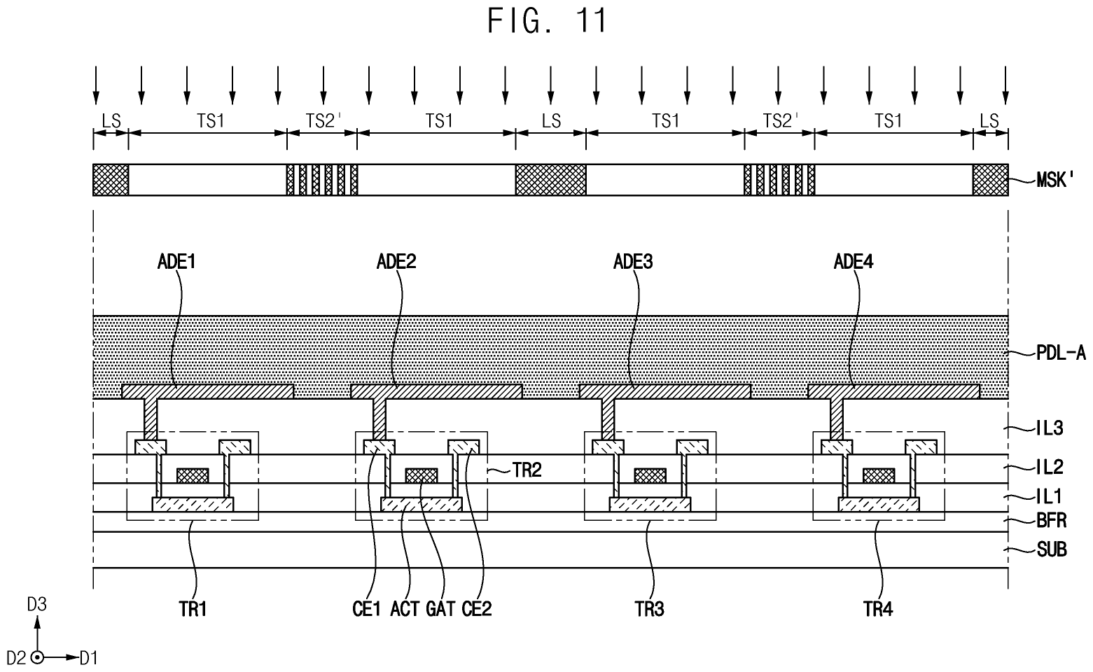

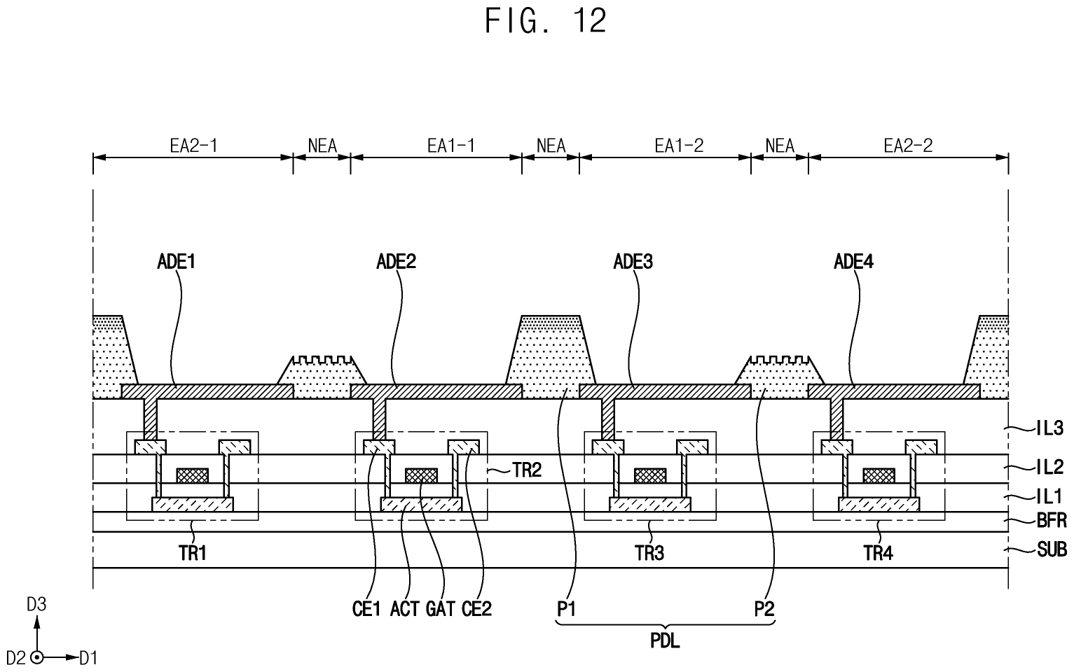

FIGS. 11 and 12 are cross-sectional views illustrating a manufacturing method of the display device of FIG. 10.

Referring to FIGS. 11 and 12, a manufacturing method of the display device 20 may be substantially the same as the manufacturing method of the display device 10 described with reference to FIGS. 4 to 9 except for the mask MSK′. Therefore, redundant descriptions will be omitted or simplified.

First, as described with reference to FIG. 4, the first to fourth driving elements TR1, TR2, TR3, and TR4 and the first to fourth pixel electrodes ADE1, ADE2, ADE3, and TR4 may be formed on the substrate SUB.

After that, as shown in FIGS. 11 and 12, the pixel-defining layer PDL may be formed on the third insulating layer IL3.

For example, the preliminary pixel-defining layer PDL-A covering the pixel electrodes ADE1, ADE2, ADE3, and ADE4 may be formed on the third insulating layer IL3. A detailed description of the preliminary pixel-defining layer PDL-A may be same as a description of FIG. 5, and thus will be omitted.

Thereafter, the pixel-defining layer PDL may be formed by patterning the preliminary pixel-defining layer PDL-A. As shown in FIG. 12, the pixel-defining layer PDL may be formed to expose a portion of each of the pixel electrodes ADE1, ADE2, ADE3, and ADE4.

In one or more embodiments, the pixel-defining layer PDL may be formed through an exposure and development process using the mask MSK′. For example, the pixel-defining layer PDL may be formed by arranging the mask MSK′ on the preliminary pixel-defining layer PDL-A, and by exposing and developing the preliminary pixel-defining layer PDL-A.

In one or more embodiments, the mask MSK′ may include a light-blocking portion LS, a first light-transmitting portion TS1, and a second light-transmitting portion TS2′. The light-blocking portion LS may be an area for blocking incident light incident on the mask MSK'. The first light-transmitting portion TS1 and the second light-transmitting portion TS2′ may be areas through which the incident light is transmitted.

In one or more embodiments, the first light-transmitting portion TS1 may have a first light transmittance, and the second light-transmitting portion TS2′ may have a second light transmittance that is lower than the first light transmittance. For example, the first light-transmitting portion TS1 may transmit the incident light as it is, and the second light-transmitting portion TS2′ may transmit only some of the incident light. For example, the second light-transmitting portion TS2′ may have a slit structure. That is, the mask MSK′ may be a slit mask.

Accordingly, the incident light might not be irradiated to an area of the preliminary pixel-defining layer PDL-A corresponding to the light-blocking portion LS. In addition, most of the incident light may be irradiated to an area of the preliminary pixel-defining layer PDL-A corresponding to the first light-transmitting portion TS1. In addition, only some of the incident light may be irradiated to an area of the preliminary pixel-defining layer PDL-A corresponding to the second light-transmitting portion TS2′.

In one or more embodiments, if the preliminary pixel-defining layer PDL-A is developed, all of the preliminary pixel-defining layer PDL-A corresponding to the light-blocking portion LS may remain, all of the preliminary pixel-defining layer PDL-A corresponding to the first light-transmitting portion TS1 may be removed, and only some of the preliminary pixel-defining layer PDL-A corresponding to the second light-transmitting unit TS2′ may be removed. That is, the preliminary pixel-defining layer PDL-A may include a positive photoresist.

Accordingly, as shown in FIG. 10, the pixel-defining layer PDL including the first portion P1 and the second portion P2 having different thicknesses may be formed. That is, the pixel-defining layer PDL may have a single-layer structure in which the first portion P1 and the second portion P2 are integrally formed through a single exposure process.

In one or more embodiments, as the second light-transmitting portion TS2′ has the slit structure, the upper surface of the second portion P2 may have the concavo-convex structure. For example, an irregular pattern or an irregular concave-convex shape may be formed on the upper surface of the second portion P2.

Thereafter, as described with reference to FIGS. 7 and 8, the light-emitting layers EL1 and EL2 may be formed. As the upper surface of the second portion P2 has the concavo-convex structure, a contact area of the upper surface of the second portion P2 may increase. Accordingly, the likelihood of a film drop-off phenomenon may be reduced of prevented. Accordingly, the light-emitting layers, such as the first light-emitting layer EL1 and the second light-emitting layer EL2, may more firmly adhere to the upper surface of the second portion P2. Accordingly, efficiency of the inkjet printing process for forming the light-emitting layer may be increased.

Then, as described with reference to FIG. 9, the common electrode CTE may be formed. Subsequently, as shown in FIG. 10, the encapsulation layer ENC may be formed on the common electrode CTE.

The present disclosure should not be construed as being limited to the embodiments set forth herein. Rather, these embodiments are provided so that this disclosure will be thorough and complete and will fully convey the concept of the present disclosure to those skilled in the art.

While the present disclosure has been particularly shown and described with reference to embodiments thereof, it will be understood by those of ordinary skill in the art that various changes in form and details may be made therein without departing from the spirit or scope of the present disclosure as defined by the following claims, with functional equivalents thereof to be included therein.

What is claimed is:

1. A display device comprising:
a substrate having light-emitting areas;
a pixel electrode above the substrate;
a pixel-defining layer exposing a portion of the pixel electrode, and comprising:
a first portion having a first thickness and having an upper surface having liquid repellency; and
a second portion having a second thickness that is less than the first thickness and having an upper surface that is lyophilic; and
a light-emitting layer above the pixel electrode.

2. The display device of claim 1, wherein the pixel-defining layer has a single-layer structure in which the first portion and the second portion are integrated.

3. The display device of claim 1, wherein the light-emitting layer covers the second portion, and is spaced apart from the upper surface of the first portion.

4. The display device of claim 1, wherein the first portion is between a respective pair of the light-emitting areas that are adjacent to each other and that emit light of different respective colors, and
wherein the second portion is between another respective pair of the light-emitting areas that are adjacent to each other and that emit light of a same color.

5. The display device of claim 1, wherein the pixel-defining layer comprises a positive photoresist.

6. The display device of claim 1, wherein the first thickness is about 1.6 μm or less, and wherein the second thickness is about 0.8 μm or less.

7. The display device of claim 1, wherein a taper angle of the first portion is greater than a taper angle of the second portion.

8. The display device of claim 1, wherein the light-emitting layer comprises a composition for the light-emitting layer,
wherein a contact angle of the composition for the light-emitting layer with respect to the upper surface of the first portion is about 50 degrees to about 70 degrees, and
wherein a contact angle of the composition for the light-emitting layer with respect to the upper surface of the second portion is about 10 degrees to about 20 degrees.

9. The display device of claim 1, wherein the pixel-defining layer comprises a liquid repellent containing a fluorine-based material, and
wherein a density of the liquid repellent in an area adjacent to the upper surface of the first portion is greater than a density of the liquid repellent in an area adjacent to the upper surface of the second portion.

10. The display device of claim 1, wherein the upper surface of the second portion has a concave and convex structure.

11. A method of manufacturing a display device, the method comprising:
forming a pixel electrode above a substrate having light-emitting areas;
forming a preliminary pixel-defining layer covering the pixel electrode on the substrate;
forming a pixel-defining layer exposing a portion of the pixel electrode, and comprising a first portion having a first thickness and having an upper surface having liquid repellency, and a second portion having a second thickness that is less than the first thickness and having an upper surface that is lyophilic, by patterning the preliminary pixel-defining layer using a mask; and
forming a light-emitting layer on the pixel electrode.

12. The method of claim 11, further comprising forming the first portion and the second portion to be integrally formed together through a same process.

13. The method of claim 11, wherein the preliminary pixel-defining layer comprises a positive photoresist.

14. The method of claim 11, wherein the preliminary pixel-defining layer comprises a liquid repellent containing a fluorine-based material.

15. The method of claim 11, wherein the mask comprises a halftone mask.

16. The method of claim 11, wherein the mask comprises a slit mask.

17. The method of claim 16, wherein the upper surface of the second portion has a concave and convex structure after the forming of the pixel-defining layer.

18. The method of claim 11, wherein the light-emitting layer is formed through an inkjet printing process.

19. The method of claim 11, wherein the light-emitting layer is formed to cover the second portion, and to be spaced apart from the upper surface of the first portion.

20. The method of claim 11, wherein the first portion is between a respective pair of the light-emitting areas that are adjacent to each other and that emit light of different respective colors, and
wherein the second portion is formed between another respective pair of the light-emitting areas that are adjacent to each other and that emit light of same color.
